(19) United States
(12) Patent Application Publication
(10) Pub. No.: US 2014/0042872 A1
(43) Pub. Date: Feb. 13, 2014

(54) POLARITY SWITCHING CIRCUIT

(71) Applicant: MICROJET TECHNOLOGY CO., LTD, Hsinchu (TW)

(72) Inventor: Shih-Chang Chen, Hsinchu (TW)

(73) Assignee: MICROJET TECHNOLOGY CO., LTD, Hsinchu (TW)

(21) Appl. No.: 13/975,924

(22) Filed: Aug. 26, 2013

Related U.S. Application Data
(63) Continuation-in-part of application No. 13/568,565, filed on Aug. 7, 2012.

(30) Foreign Application Priority Data
Jul. 5, 2013 (TW) 102124141

(51) Int. Cl. H01L 41/04

(52) U.S. Cl. CPC H01L 41/042
USPC 310/317

(57) ABSTRACT

A polar switch circuit is disclosed. The polar switch circuit comprises the first to the forth transistor switches and the first to the second filter circuits. The first and forth transistor switches are controlled by a first pulse-width modulating signal. The second and third transistor switches are controlled by a second pulse-width modulating signal. The second and the fourth transistor switches are connected with a DC high voltage, and connected with the first and third transistor switches, respectively. The first filter circuit is connected with the first transistor switch, the second transistor switch and a contact of a piezoelectric actuator. The second filter circuit is connected with the third transistor switch, the forth transistor switch and another contact of the piezoelectric actuator. When the first and second pulse-width modulating signals switch high/low level in interlaced, an output AC voltage can be smooth and deliver to the contacts of the piezoelectric actuator.

### CROSS-REFERENCE TO RELATED APPLICATION

This application is a continuation-in-part of U.S. patent application Ser. No. 13/568,565 filed on Aug. 7, 2012, and entitled “POLARITY SWITCHING CIRCUIT”. The entire disclosures of the above application are all incorporated herein by reference.

### FIELD OF THE INVENTION

The invention is related to a polarity switching circuit, and more particularly to a polarity switching circuit for outputting an output AC voltage with a smooth waveform to drive a piezoelectric actuator.

### BACKGROUND OF THE INVENTION

With the progress of technology, various electronic products have been developed for stimulating the growth of the information technology market. Undoubtedly, such trend will carry on. Also, with the advancement of the microelectronic technology, the electronic products will be more versatile and more miniaturized. Besides, the portability of the electronic products will be enhanced as well. Nowadays, the user can handle all kinds of business easily with various electronic products. In recent years, the so-called piezoelectric actuator have been developed and applied to electronic products. The piezoelectric actuator have the advantages of low voltage, high immunity to noise, small size, fast response, low heat radiation, high sophistication, high conversion efficiency, and high controllability.

The piezoelectric actuator generally requires an AC voltage that is applied thereto to drive the piezoelectric actuator to carry out high-speed periodically operations. Hence, the piezoelectric actuator needs a driving system to operate. The driving system is used to convert a DC voltage into an AC voltage for driving the piezoelectric actuator. Referring to FIG. 1, the traditional driving system 1 is used to convert a DC input voltage V_{DC} into output AC voltages Vₒ₁ and Vₒ₂ for driving a piezoelectric actuator 9 shown in FIG. 2A. The driving system 1 includes a boost circuit 10, a voltage multiplier 11, and a polarity switching circuit 12. The boost circuit 10 is connected to the DC input voltage V_{DC} and configured to convert the DC input voltage V_{DC} into a transient voltage V_{T} by the switching operations of the internal switch elements and the energy storage and filtering operations carried out by the internal inductors, capacitors, and diodes. The voltage multiplier 11 is connected to the transient voltage V_{T} and configured to multiply the transient voltage V_{T} by 4 to generate a DC high voltage V_{B}. The polarity switching circuit 12 is used to convert the DC high voltage V_{B} into output AC voltages Vₒ₁ and Vₒ₁ for driving the piezoelectric actuator 9.

Referring to FIGS. 2A, 2B, and 3 with reference to FIG. 1, in which FIG. 2A shows the internal circuitry of the polarity switching circuit of FIG. 1, and FIG. 2B illustrates the operation of the polarity switching circuit of FIG. 2A as the digital signal f_{sw} is low. Also, FIG. 3 shows the timing of the voltage signals of FIG. 2A or FIG. 2B. The traditional polarity switching circuit 12 is connected to the DC high voltage V_{B}, the input DC low voltage Vᵢₙ, and the digital signal f_{sw} and configured to convert the DC high voltage V_{B} into output AC voltages Vₒ₁ and Vₒ₂ for driving the piezoelectric actuator 9 to operate repetitively. The polarity switching circuit 12 includes a first current-limiting resistor R21, a second current-limiting resistor R22, a third current-limiting resistor R23, a first transistor switch Q21, a second transistor switch Q22, a third transistor switch Q23, a fourth transistor switch Q24, a fifth transistor switch Q25, a sixth transistor switch Q26, and a seventh transistor switch Q27.

As the digital signal f_{sw} is high and is sent to the control terminal of the first transistor switch Q21 and the control terminal of the sixth transistor switch Q26, the first transistor switch Q21 and the sixth transistor switch Q26 that are connected to the ground terminal G will turn on. As the first current-limiting resistor R21 is connected to the first transistor switch Q21, the circuit branch consisted of the first current-limiting resistor R21 will be connected to the ground terminal G. Meanwhile, the second transistor switch Q22 and the fourth transistor switch Q24 will turn off as the control terminal of the second transistor switch Q22 and the control terminal of the fourth transistor switch Q24 are connected to the circuit branch consisted of the first current-limiting resistor R21, thereby driving the voltage level of the circuit branch consisted of the second current-limiting resistor R22 to a high level due to the high DC voltage V_{B}. Hence, the third transistor switch Q23 will turn on as the control terminal of the third transistor switch Q23 is connected to the circuit branch consisted of the second current-limiting resistor R22. Meanwhile, the control terminal of the seventh transistor switch Q27 is connected to the digital signal f_{sw} with a high level. Therefore, the seventh transistor switch Q27 is also turned on. As the third current-limiting resistor R23 is connected to the seventh transistor switch Q27, the circuit branch consisted of the third current-limiting resistor R23 is connected to the ground terminal G. Also, as the control terminal of the fifth transistor switch Q25 is connected to the circuit branch consisted of the third current-limiting resistor R23, the fifth transistor switch Q25 is turned off. Therefore, the current will flow in the direction as indicated by the arrows shown in FIG. 2A.

As the digital signal f_{sw} is low, as shown in FIG. 2B, the operations of all the transistor switches are reverse to the operations of all the transistor switches indicated in FIG. 2A. Under this circumstance, the directions of the current flow can be indicated by the arrows shown in FIG. 2B. Consequently, the output AC voltages Vₒ₁ and Vₒ₂ of the polarity switching circuit 12 will have a square waveform on the piezoelectric actuator 9, as indicated by the waveform of the voltage signal of (Vₒ₁-Vₒ₂) shown in FIG. 3.

As the output AC voltages Vₒ₁ and Vₒ₂ of the traditional polarity switching circuit 12 have square waveforms on the piezoelectric actuator 9, the piezoelectric actuator 9 is rapidly charged as the voltage levels of the output AC voltages Vₒ₁ and Vₒ₂ are boosted or bucked rapidly. Although the piezoelectric actuator 9 can reach the peak of its amplitude due to the rapid charging of the piezoelectric actuator 9, the power loss is increased as well. More disadvantageously, as the traditional polarity switching circuit 12 is configured to charge the piezoelectric actuator 9 rapidly with square AC waves, the piezoelectric actuator 9 will vibrate under a natural resonant frequency. Such vibration will cause tremendous noise. Moreover, because the traditional polarity switching circuit 12 is consisted of more transistor switches which are seven transistor switches shown in FIG. 2A, the production cost of the traditional polarity switching circuit 12 is increased, and the switching loss of the traditional polarity switching circuit 12 resulting from the turning on or turning off operations of several transistor switches is increased.

Hence, it is needed to develop a polarity switching circuit to address the problems encountered by the prior art. The invention can meet this need.

### SUMMARY OF THE INVENTION

An object of the invention is to provide a polarity switching circuit for addressing the problems of the huge power loss and the tremendous noise generated during the operation phase of the piezoelectric actuator. Moreover, because the traditional polarity switching circuit is consisted of more transistor switches, the production cost and the switching loss of the traditional polarity switching circuit are increased.

To this end, the present invention provides a polarity switching circuit for converting a DC high voltage into an output AC voltage for driving a piezoelectric actuator. The inventive polarity switching circuit includes a first switch circuit, a second switch circuit, a first filter circuit, and a second filter circuit. The first switch circuit is used for receiving a first pulse-width modulating (PWM) signal and a second pulse-width modulating signal, wherein the first pulse-width modulating signal and the second pulse-width modulating signal are switching inversely, and a terminal of the first switch circuit is connected to a ground terminal, and another terminal of the first switch circuit is connected to the DC high voltage. The second switch circuit is used for receiving the first pulse-width modulating signal and the second pulse-width modulating signal, wherein the first pulse-width modulating signal and the second pulse-width modulating signal are switching inversely, and a terminal of the second switch circuit is connected to the ground terminal, and another terminal of the second switch circuit is connected to the DC high voltage. The first filter circuit is connected to the first switch circuit, a first contact of the piezoelectric actuator, and the ground terminal. The second filter circuit is connected to the second switch circuit, a second contact of the piezoelectric actuator, and the ground terminal. When the first pulse-width modulating signal and the second pulse-width modulating signal are alternately and respectively switching between a high level and a low level, the output AC voltage is changed into a smoothed AC waveform, thereby providing an output AC voltage with a smoothed waveform for the piezoelectric actuator.

Now the foregoing and other features and advantages of the invention will be best understood through the following descriptions with reference to the accompanying drawings, in which:

### BRIEF DESCRIPTION OF THE DRAWINGS

FIG. 1 is a circuit block diagram showing the driving system for piezoelectric actuator according to the prior art;

FIG. 2A shows the internal circuitry of the polarity switching circuit of FIG. 1;

FIG. 2B illustrates the operation of the polarity switching circuit of FIG. 1 as the digital signal f_{sw} is low;

FIG. 3 shows the timing of the voltage signals of FIG. 2A or FIG. 2B;

FIG. 4A shows the internal circuitry of the polarity switching circuit according to a preferred embodiment of the invention;

FIG. 4B illustrates the circuit operation of the polarity switching circuit of FIG. 4A as the first pulse-width modulating signal PWM1 is low and the second pulse-width modulating signal PWM2 is switching between a low level and a high level;

FIGS. 5A, 5B and 5C are respectively the timing diagrams of the voltage signals of FIGS. 4A and 4B;

FIG. 6 shows an alternative example of the first filter circuit and the second filter circuit of FIG. 4A;

FIGS. 7A and 7B show alternative examples of the polarity switching circuit of FIGS. 4A and 4B; and

FIG. 8 is a structural view of a mechanical body incorporating the piezoelectric actuator of FIG. 4A.

### DESCRIPTION OF THE PREFERRED EMBODIMENT

Several exemplary embodiments embodying the features and advantages of the invention will be expounded in following paragraphs of descriptions. It is to be realized that the present invention is allowed to have various modification in different respects, all of which are without departing from the scope of the present invention, and the description herein and the drawings are to be taken as illustrative in nature, but not to be taken as a confinement for the invention.

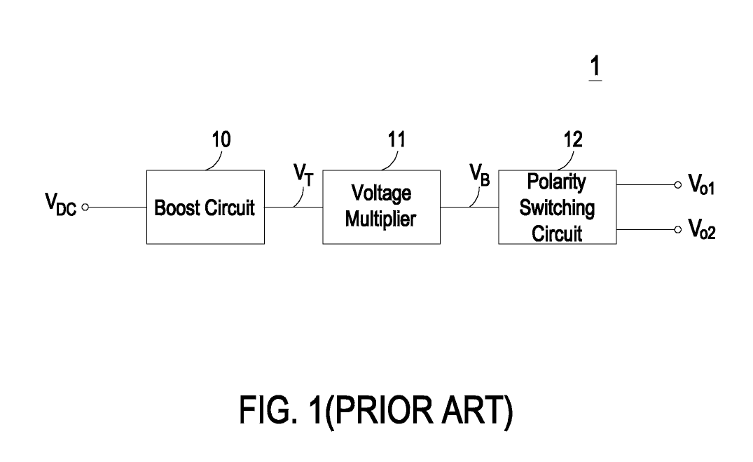

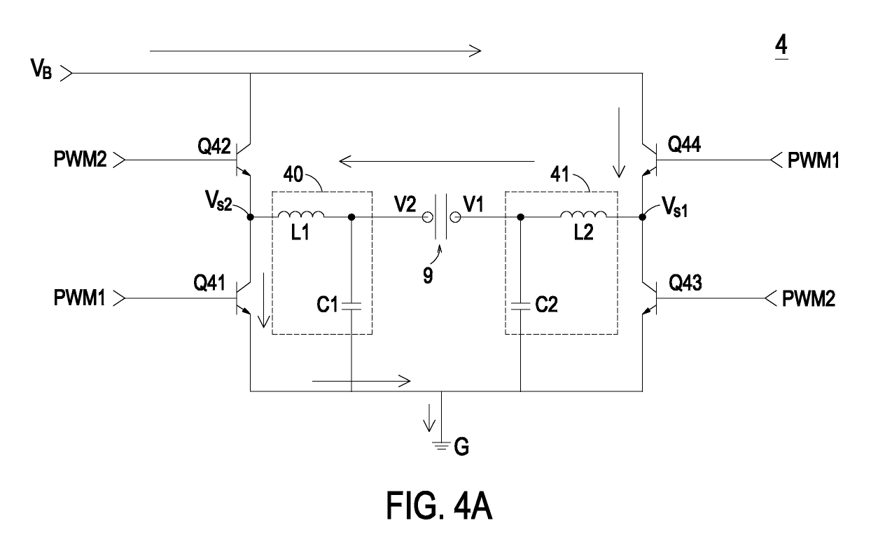

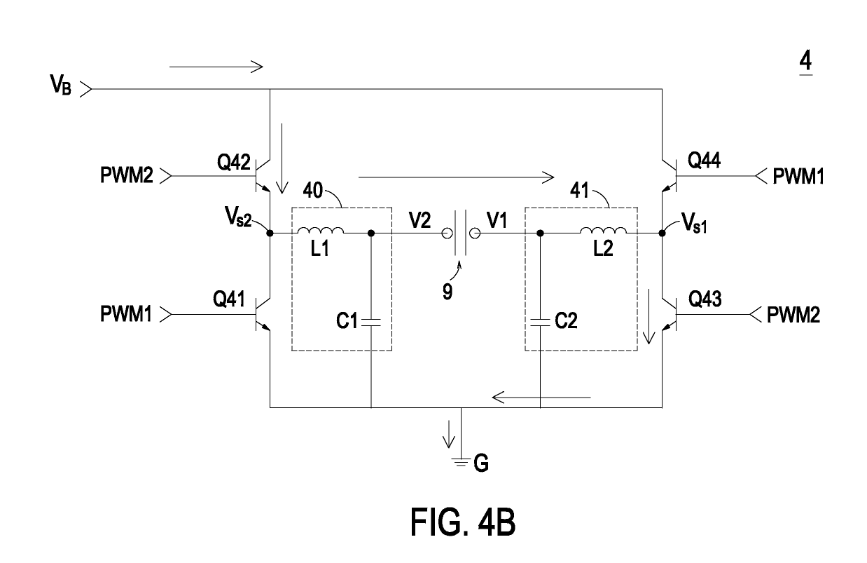

Referring to FIGS. 4A and 4B, in which FIG. 4A shows the internal circuitry of the polarity switching circuit according to a preferred embodiment of the invention, and FIG. 4B illustrates the circuit operation of the polarity switching circuit of FIG. 4A as the first pulse-width modulating signal PWM1 is low and the second pulse-width modulating signal PWM2 is switching between a low level and a high level. As shown in FIGS. 4A and 4B, the polarity switching circuit 4 is connected to a DC high voltage V_{B} and configured to convert the DC high voltage V_{B} into output AC voltages V₁ and V₂ according to a first pulse-width modulating signal PWM1 and a second pulse-width modulating signal PWM2, thereby driving a piezoelectric actuator 9 to operate repetitively. The DC high voltage V_{B} is outputted from a voltage multiplier 11 shown in FIG. 1. The polarity switching circuit 4 includes a first transistor switch Q41, a second transistor switch Q42, a third transistor switch Q43, a fourth transistor switch Q44, a first filter circuit 40, and a second filter circuit 41.

A control terminal of the first transistor switch Q41 is connected to the first pulse-width modulating signal PWM1. A current input terminal of the first transistor switch Q41 is connected to the first filter circuit 40. A current output terminal of the first transistor switch Q41 is connected to a ground terminal G. A control terminal of the second transistor switch Q42 is connected to the second pulse-width modulating signal PWM2. A current input terminal of the second transistor switch Q42 is connected to the DC high voltage V_{B}. A current output terminal of the second transistor switch Q42 is connected to the first filter circuit 40 and the current input terminal of the first transistor switch Q41. The first filter circuit 40 is connected to a contact of the piezoelectric actuator 9 (receiving the output AC voltage V2) and the ground terminal G.

A control terminal of the third transistor switch Q43 is connected to the second pulse-width modulating signal PWM2. A current input terminal of the third transistor switch Q43 is connected to the second filter circuit 41. A current output terminal of the third transistor switch Q43 is connected to the ground terminal G. A control terminal of the fourth transistor switch Q44 is connected to the first pulse-width modulating signal PWM1. A current input terminal of the fourth transistor switch Q44 is connected to the DC high voltage V_{B}. A current output terminal of the fourth transistor switch Q44 is connected to the second filter circuit 41 and the current input terminal of the third transistor switch Q43. The second filter circuit 41 is connected to another contact of the piezoelectric actuator 9 (receiving the output AC voltage V1) and the ground terminal G. In this embodiment, a first switch circuit is consisted of the first transistor switch Q41 and the second transistor switch Q42, and a second switch circuit is consisted of the third transistor switch Q43 and the fourth transistor switch Q44.

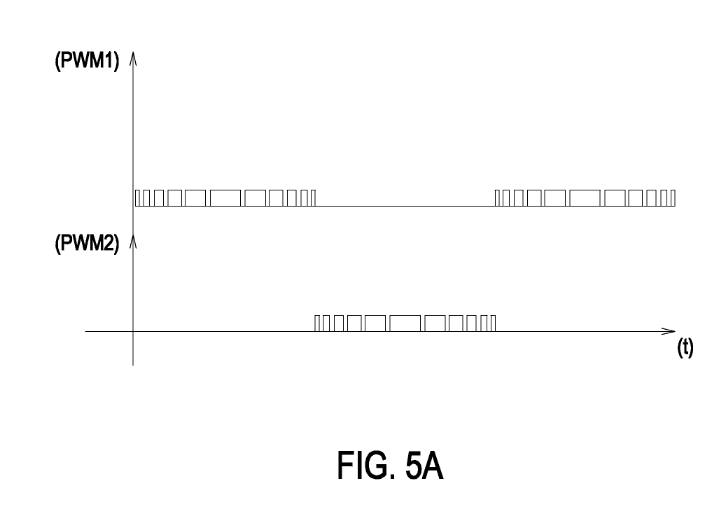

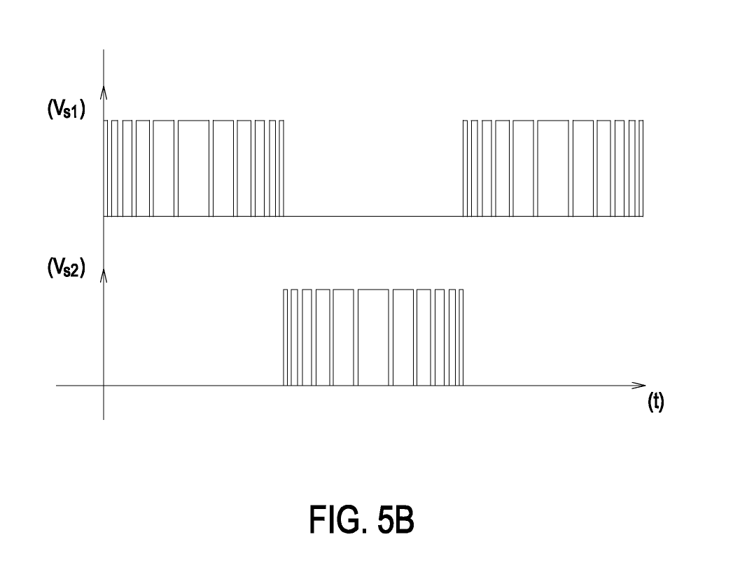

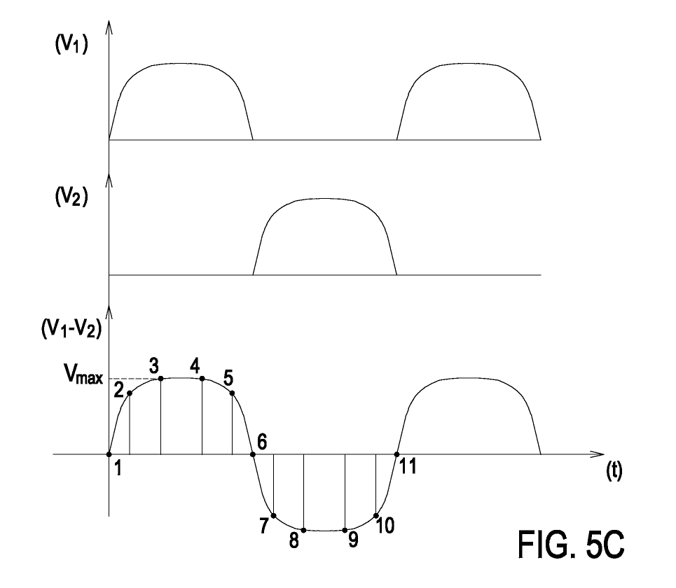

Referring to FIGS. 5A, 5B, and 5C with reference to FIGS. 4A and 4B, in which FIGS. 5A, 5B, and 5C are the timing diagrams of the voltage signals of FIGS. 4A and 4B, respectively. As shown in FIGS. 4A, 4B, 5A, 5B, and 5C, the first pulse-width modulating signal PWM1 and the second pulse-width modulating signal PWM2 are alternately switched between the high level and the low level. That is, when the first pulse-width modulating signal PWM1 is switching between the high level and the low level, the second pulse-width modulating signal PWM2 is low. On the contrary, when the second pulse-width modulating signal PWM2 is switching between the high level and the low level, the first pulse-width modulating signal PWM1 is low. In other words, the first pulse-width modulating signal PWM1 and the second pulse-width modulating signal PWM2 are switching inversely.

When the first pulse-width modulating signal PWM1 is switching between the high level and the low level and the second pulse-width modulating signal PWM2 is low, the second pulse-width modulating signal PWM2 with the low level will drive the second transistor switch Q42 and the third transistor switch Q43 to turn off. Meanwhile, the high-frequency switching of the first pulse-width modulating signal PWM1 between the high level and the low level will drive the first transistor switch Q41 and the fourth transistor switch Q44 to switch synchronously. That is, the first transistor switch Q41 and the fourth transistor switch Q44 are turned on or turned off simultaneously. Therefore, when first transistor switch Q41 and the fourth transistor switch Q44 are turned on, the current will flow in the direction indicated by the arrows shown in FIG. 4A.

On the contrary, when the second pulse-width modulating signal PWM2 is switching between the high level and the low level and the first pulse-width modulating signal PWM1 is low, the operations of the transistor switches are reversed. That is, the first pulse-width modulating signal PWM1 with the low level will drive the first transistor switch Q41 and the fourth transistor switch Q44 to turn off. Meanwhile, the high-frequency switching of the second pulse-width modulating signal PWM2 between the high level and the low level will drive the second transistor switch Q42 and the third transistor switch Q43 to switch synchronously. That is, the second transistor switch Q42 and the third transistor switch Q43 are turned on or turned off simultaneously. Therefore, when the second transistor switch Q42 and the third transistor switch Q43 are turned on, the current will flow in the direction indicated by the arrows shown in FIG. 4B.

Hence, when the timing of the first pulse-width modulating signal PWM1 and the timing of the second pulse-width modulating signal PWM2 are set as indicated in FIG. 5A, that is, when the frequency of the first pulse-width modulating signal PWM1 and the frequency of the second pulse-width modulating signal PWM2 are respectively varied from a high value to a low value and then to a high value, a second switching voltage Vₛ₂ is generated between the current input terminal of the first transistor switch Q41 and the current output terminal of the second transistor switch Q42, and a first switching voltage Vₛ₁ is generated between the current input terminal of the third transistor switch Q43 and the current output terminal of the fourth transistor switch Q44. Also, as shown in FIG. 5B, the first switching voltage Vₛ₁ and the second switching voltage Vₛ₂ that are pulse voltages will vary in synchronization with the first pulse-width modulating signal PWM1 and the second pulse-width modulating signal PWM2 from a high-frequency level to a low-frequency level and then to a high-frequency level. The first switching voltage Vₛ₁ and the second switching voltage Vₛ₂ will be filtered by the second filter circuit 41 and the first filter circuit 40 respectively, thereby generating output AC voltages V₁ and V₂ with smoothed AC waveforms, as shown in FIG. 5C.

Referring to FIG. 5C, the driving electric energy applying to the piezoelectric actuator 9, that is, the difference value between the output AC voltage V₁ and the output AC voltage V₂, will reach a first fractional value of the maximum voltage Vₘₐₓ linearly within a first time period after the polarity switching circuit 4 starts operating, as indicated by the curve between the numerical marking 1 and the numerical marking 2. Afterwards, the waveform of the driving electric energy applying to the piezoelectric actuator 9 will smoothly boost up and reach the maximum voltage Vₘₐₓ within a first predetermined time period, as indicated by the curve between the numerical marking 2 and the numerical marking 3. Afterwards, the waveform of the driving electric energy applying to the piezoelectric actuator 9 will stay level within a second time period, as indicated by the curve between the numerical marking 3 and the numerical marking 4. Afterwards, the waveform of the driving electric energy applying to the piezoelectric actuator 9 will smoothly decline and reach a second fractional value of the maximum voltage Vₘₐₓ linearly within a second predetermined time period, as indicated by the curve between the numerical marking 4 and the numerical marking 5. Finally, the waveform of the driving electric energy applying to the piezoelectric actuator 9 will drop to zero linearly, as indicated by the curve between the numerical marking 5 and the numerical marking 6. As to the waveform of the driving electric energy applying to the piezoelectric actuator 9 indicated by the curve between the numerical marking 6 and the numerical marking 11 (i.e. reverse to the segment of the waveform indicated by the curve between the numerical marking 1 and the numerical marking 6), it is not intended to describe red redundantly as the characteristics of this segment of waveform are similar to those of the segment of waveform indicated by the curve between the numerical marking 1 and the numerical marking 6. Also, the rising rate, the falling rate, the knee point radian, and the maintaining time of the maximum voltage Vₘₐₓ of the smooth AC waveform of the output AC voltages V₁ and V₂ outputted from the polarity switching circuit 4 can be varied according to the practical requirement by adjusting the pulse widths of the first pulse-width modulating signal PWM1 and the second pulse-width modulating signal PWM2.

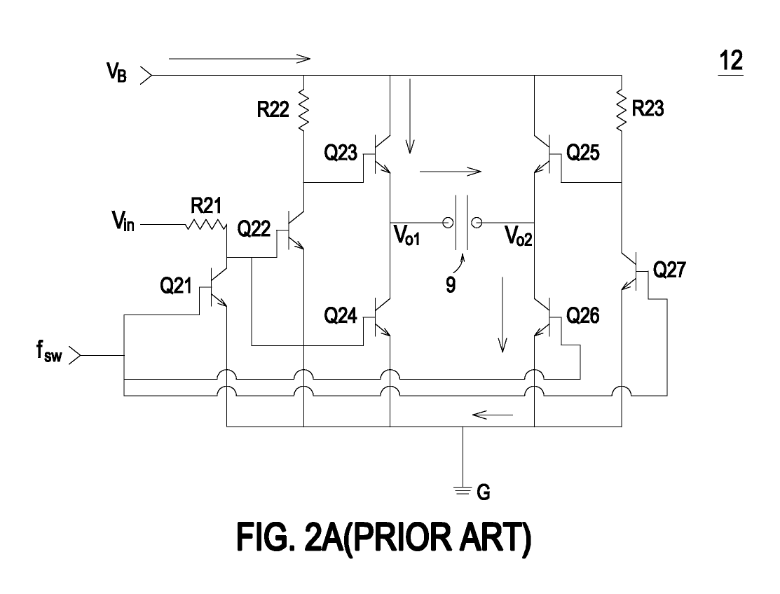

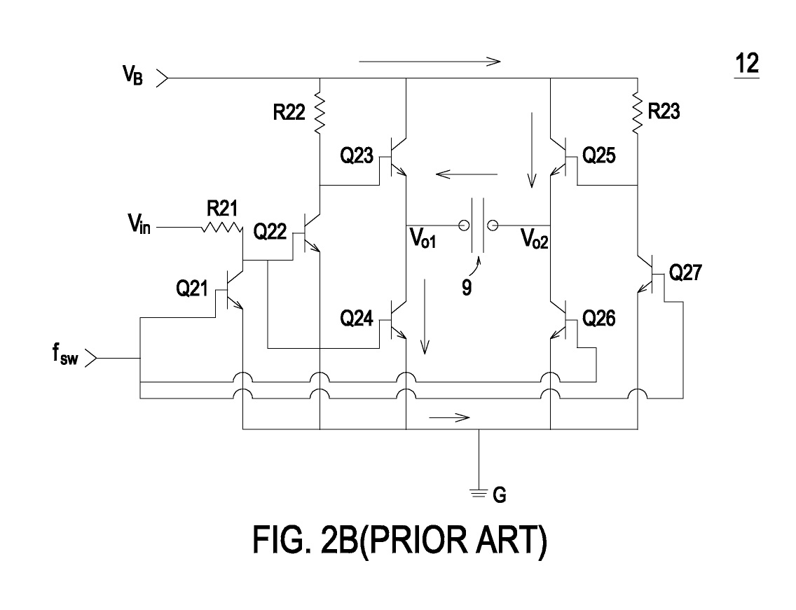

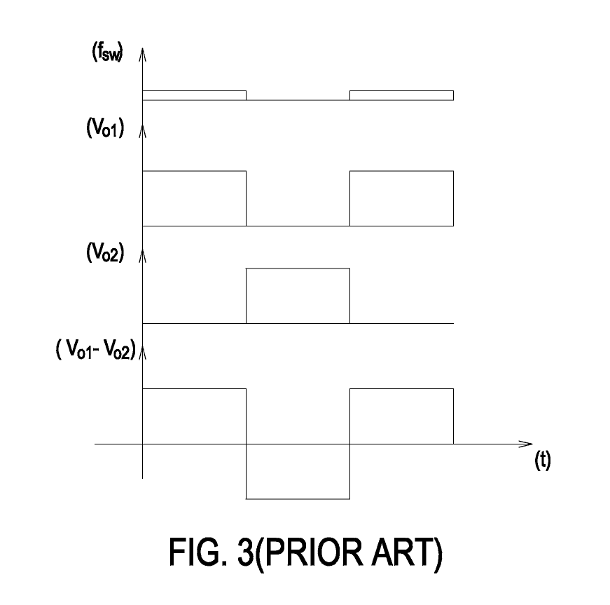

The output AC voltages V₁ and V₂ of the inventive polarity switching circuit 4 have smooth AC waveforms and are applied to the two contacts of the piezoelectric actuator 9. According to the prior art as shown in FIG. 2A, the output AC voltages Vₒ₁ and Vₒ₂ of the traditional polarity switching circuit have square AC waveforms and are applied to the piezoelectric actuator 9. Consequently, the inventive polarity switching circuit 4 can charge the piezoelectric actuator 9 moderately, which would reduce the power loss as a result of rapid charging. More advantageously, the vibrations of the piezoelectric actuator 9 under a natural resonant frequency can be suppressed, thereby avoiding the noise generated during the operation phase of the piezoelectric actuator 9. In addition, comparing with the traditional polarity switching circuit 12 consisted of seven transistor switches, as shown in FIG. 2A, the inventive polarity switching circuit 4 is consisted of only four transistor switches (from the first transistor switch Q41 to the fourth transistor switch Q44). Consequently, by using the polarity switching circuit 4, the production cost is reduced, and the switching loss of the polarity switching circuit resulting from the turning on or turning off operations of the transistor switches can be reduced.

In some embodiments, the first filter circuit 40 can include a first inductor L₁ and a first capacitor C₁, as shown in FIG. 4A. One terminal of the first inductor L₁ is connected to the current input terminal of the first transistor switch Q41 and the current output terminal of the second transistor switch Q42. One terminal of the first capacitor C₁ is connected to a contact of the piezoelectric actuator 9 and the other terminal of the first inductor L₁. The other terminal of the first capacitor C₁ is connected to the ground terminal G. The second filter circuit 41 can include a second inductor L₂ and a second capacitor C₂. One terminal of the second inductor L₂ is connected to the current input terminal of the third transistor switch Q43 and the current output terminal of the fourth transistor switch Q44. One terminal of the second capacitor C₂ is connected to another contact of the piezoelectric actuator 9 and the other terminal of the second inductor L₂. The other terminal of the second capacitor C₂ is connected to the ground terminal G.

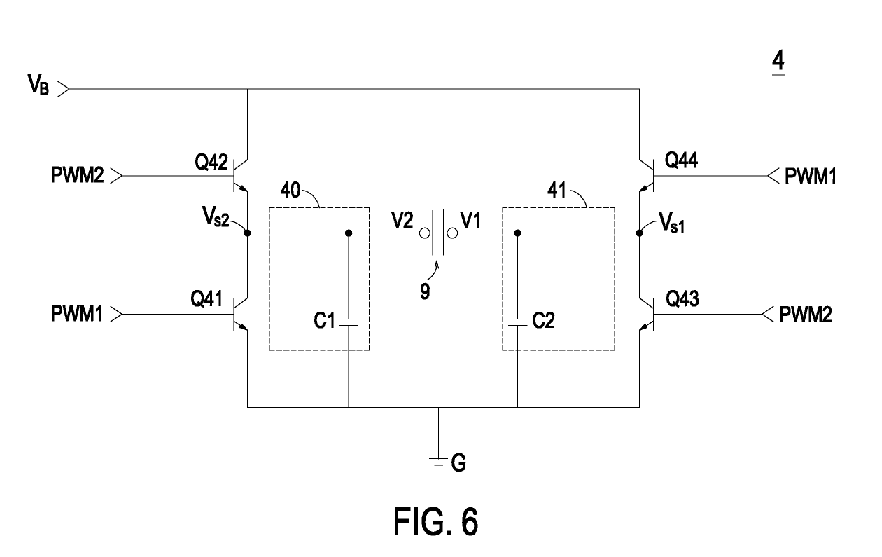

In some embodiments, the first filter circuit 40 can include a first capacitor C₁ only, as shown in FIG. 6. One terminal of the first capacitor C₁ is connected to a contact of the piezoelectric actuator 9, the current input terminal of the first transistor switch Q41, and the current output terminal of the second transistor switch Q42. The other terminal of the first capacitor C₁ is connected to the ground terminal G. The second filter circuit 41 can include a second capacitor C₂ only. The second capacitor C₂ is connected to another contact of the piezoelectric actuator 9, the current input terminal of the third transistor switch Q43, and the current output terminal of the fourth transistor switch Q44. The other terminal of the second capacitor C₂ is connected to the ground terminal G.

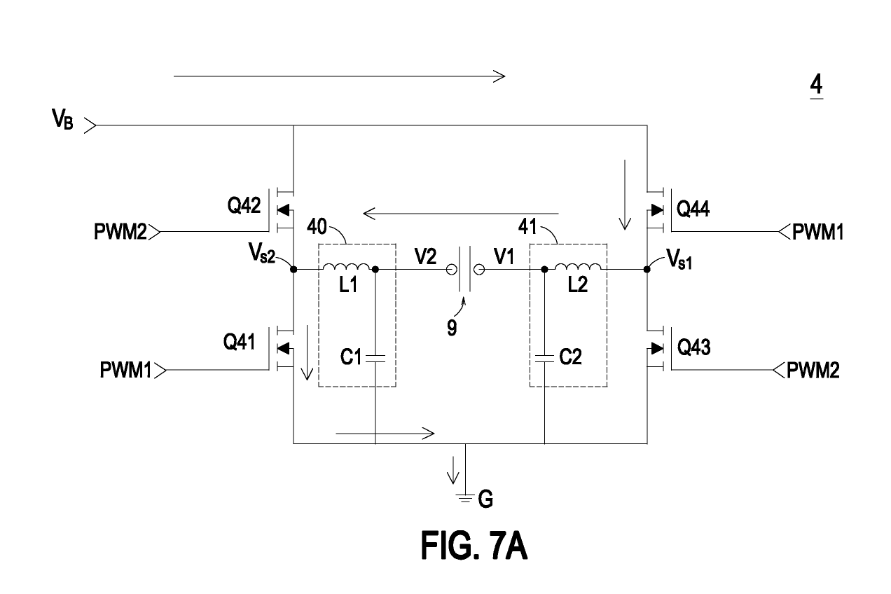

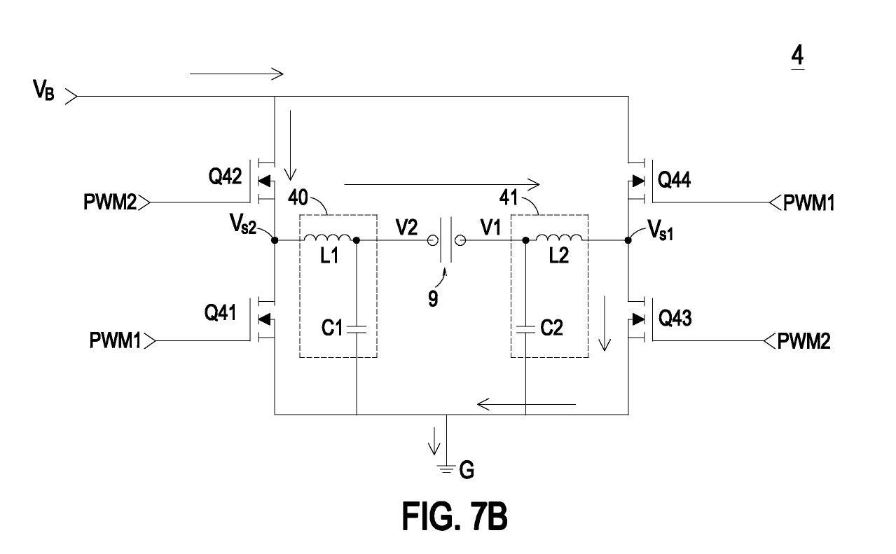

In some embodiments, the transistor switches Q41˜Q44 can be implemented by NPN bipolar junction transistors (BJTs), as shown in FIG. 4A. Under this circumstance, the control terminals, the current input terminals, and the current output terminals of the transistor switches Q41˜Q44 are constituted by the bases, the collectors, and the emitters, respectively. Nonetheless, in alternative embodiments, the transistor switches Q41˜Q44 can be implemented by field-effect transistors (FETs), as shown in FIGS. 7A and 7B. Under this circumstance, the control terminals, the current input terminals, and the current output terminals of the transistor switches Q41˜Q44 are constituted by the gates, the sources, and the drains, respectively. As the circuit topology and operation principle of the polarity switching circuit 12 of FIGS. 7A and 7B are similar to those of the polarity switching circuit 12 of FIGS. 4A and 4B, it is not intended to describe the details to the circuit topology and operation principle of the polarity switching circuit 4 of FIGS. 7A and 7B redundantly herein.

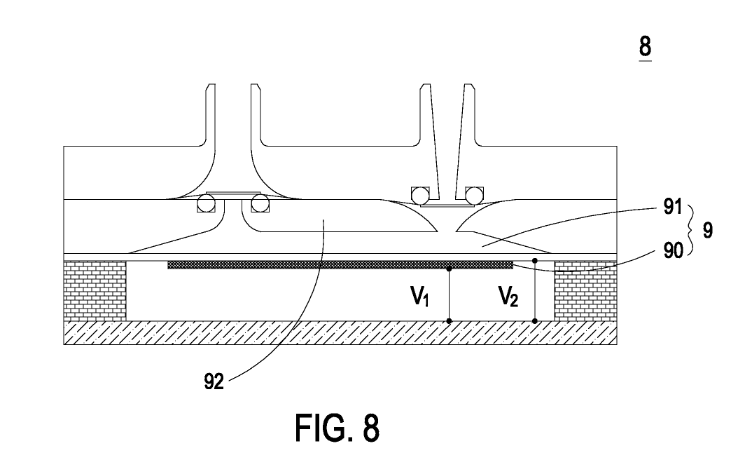

Referring to FIG. 8, the structural view of a mechanical body incorporating the piezoelectric actuator of FIG. 4A is shown. As shown in FIG. 8, the mechanical body may be a fluid transfer device 8 that is applicable to biomedical technology, computer technology, printing technology, or energy industry for transferring gas or liquid. The fluid transfer device 8 may be a pump in an inkjet printer for converting electric energy into mechanical energy. The piezoelectric actuator 9 includes an actuating piece 90 and a vibrating film 91 that are respectively connected to the output AC voltage V₁ and the output AC voltage V₂. The output AC voltage V₁ and the output AC voltage V₂ are used to drive the actuating piece 90 and the vibrating film 91 to operate repetitively for allowing the pressure chamber 92 to be compressed or expanded, thereby enabling the fluid transfer device 8 to transfer fluid.

In conclusion, the inventive polarity switching circuit employs four transistor switches and two filters to output AC voltages with smoothed AC waveforms. Thus, the power loss of the piezoelectric actuator is reduced and the noise of the piezoelectric actuator is suppressed. Meanwhile, the inventive polarity switching circuit is consisted of only four transistor switches. Hence the production cost of the inventive polarity switching circuit can be reduced, and the switching loss of polarity switching circuit resulting from turning on or turning off operations of the transistor switches can be reduced.

While the invention has been described in terms of what are presently considered to be the most practical and preferred embodiments, it is to be understood that the invention need not be restricted to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the invention which is defined by the appended claims.

What is claimed is:

1. A polarity switching circuit for converting a DC high voltage into an output AC voltage for driving a piezoelectric actuator, the polarity switching circuit comprising:
a first switch circuit receiving a first pulse-width modulating signal and a second pulse-width modulating signal, wherein the first pulse-width modulating signal and the second pulse-width modulating signal are switching inversely, a terminal of the first switch circuit is connected to a ground terminal, and another terminal of the first switch circuit is connected to the DC high voltage;
a second switch circuit receiving the first pulse-width modulating signal and the second pulse-width modulating signal, wherein the first pulse-width modulating signal and the second pulse-width modulating signal are switching inversely, a terminal of the second switch circuit is connected to the ground terminal, and another terminal of the second switch circuit is connected to the DC high voltage;
a first filter circuit connected to the first switch circuit, a first contact of the piezoelectric actuator, and the ground terminal; and
a second filter circuit connected to the second switch circuit, a second contact of the piezoelectric actuator, and the ground terminal;
wherein when the first pulse-width modulating signal and the second pulse-width modulating signal are alternately and respectively switching between a high level and a low level, the output AC voltage is changed into a smoothed waveform, thereby providing the output AC voltage with the smoothed waveform for the piezoelectric actuator.

2. The polarity switching circuit according to claim 1, wherein the first switch circuit is consisted of a first transistor switch and a second transistor switch, and the second switch circuit is consisted of a third transistor switch and a fourth transistor switch.

3. The polarity switching circuit according to claim 2, wherein each of the first, the second, the third and the fourth transistor switches has a control terminal, a current input terminal, and a current output terminal, wherein the current input terminal of the first transistor switch and the current output terminal of the second transistor switch are connected to each other, and the current input terminal of the third transistor switch and the current output terminal of the fourth transistor switch are connected to each other.

4. The polarity switching circuit according to claim 3, wherein the first filter circuit includes a first inductor and a first capacitor, wherein the first inductor is connected to the first contact of the piezoelectric actuator, the current input terminal of the first transistor switch, and the current output terminal of the second transistor switch, and the first capacitor is connected to the first contact of the piezoelectric actuator, the first inductor, and the ground terminal; and
wherein the second filter circuit includes a second inductor and a second capacitor, wherein the second inductor is connected to the second contract of the piezoelectric actuator, the current input terminal of the third transistor switch, and the current output terminal of the fourth transistor switch, and the second capacitor is connected to the second contract of the piezoelectric actuator, the second inductor and the ground terminal.

5. The polarity switching circuit according to claim 3, wherein the first filter circuit includes a first capacitor connected to the first contact of the piezoelectric actuator, the current input terminal of the first transistor switch, the current output terminal of the second transistor switch, and the ground terminal; and
wherein the second filter circuit includes a second capacitor connected to the second contact of the piezoelectric actuator, the current input terminal of the third transistor switch, the current output terminal of the fourth transistor switch, and the ground terminal.

6. The polarity switching circuit according to claim 2, wherein the first, the second, the third and the fourth transistor switches are bipolar junction transistors.

7. The polarity switching circuit according to claim 6, wherein the first, the second, the third and the fourth transistor switches are NPN bipolar junction transistors.

8. The polarity switching circuit according to claim 2, wherein the first, the second, the third and the fourth transistor switches are field-effect transistors.

9. The polarity switching circuit according to claim 1, wherein when the first pulse-width modulating signal is switching between a high level and a low level, the second pulse-width modulating signal is at a low level, and when the second pulse-width modulating signal is switching between a high level and a low level, the first pulse-width modulating signal is at a low level.

10. The polarity switching circuit according to claim 1, wherein the first pulse-width modulating signal and the second pulse-width modulating signal are set to vary from a high-frequency level to a low-frequency level and then to a high-frequency level.

11. The polarity switching circuit according to claim 1, wherein the output AC voltage with the smoothed waveform reaches a first fractional value of a maximum voltage linearly within a first time period after the polarity switching circuit starts operating, and smoothly boosts up and reaches the maximum voltage within a first predetermined time period; and then the output AC voltage with the smoothed waveform stays level within a second time period and smoothly declines and reaches a second fractional value of the maximum voltage linearly within a second predetermined time period; and then the output AC voltage drops to zero linearly.
